(19) United States
(12) Patent Application Publication
(10) Pub. No.: US 2008/0178805 A1
(43) Pub. Date: Jul. 31, 2008

(54) Mid-chamber gas distribution plate, tuned plasma flow control grid and electrode

(75) Inventors: Alexander M. Paterson, (US); John P. Holland, (US); Theodoros Panagopoulos, (US); Edward P. Hammond, (US); Brian K. Hatcher, (US); Valentin N. Todorow, (US); Dan Katz, (US)

Correspondence Address: LAW OFFICE OF ROBERT M. WALLACE, 2112 EASTMAN AVENUE, SUITE 102, VENTURA, CA, 93003, US

(73) Assignee: APPLIED MATERIALS, INC.

(21) Appl. No.: 11/998,468

(22) Filed: Nov. 28, 2007

Related U.S. Application Data
(60) Provisional application No. 60/873,103, filed on Dec. 5, 2006.

(51) Int. Cl. C23C 16/513

(52) U.S. Cl. 118/723 I; 118/723 R

(57) ABSTRACT

A plasma reactor is provided for processing a workpiece such as a semiconductor wafer or a dielectric mask. The reactor chamber has a ceiling, a side wall and a workpiece support pedestal inside the chamber and facing the ceiling along an axis of symmetry and defining a chamber volume between the pedestal and the ceiling. An RF plasma source power applicator is provided at the ceiling. An in-situ electrode body inside the chamber lies divides the chamber into upper and lower chamber regions. The in-situ electrode comprises plural flow-through passages extending parallel to the axis and having different opening sizes, the passages being radially distributed by opening size in accordance with a desired radial distribution of gas flow resistance through the in-situ electrode body.

### CROSS-REFERENCE TO RELATED APPLICATIONS

This application claims benefit of U.S. Provisional Application Ser. No. 60/873,103, filed Dec. 5, 2006.

### BACKGROUND

Plasma process uniformity across a workpiece, such as a semiconductor wafer, is limited by non-uniformity of plasma ion distribution and process gas flow distribution. Efforts to improve process uniformity across the wafer can entail changing the radial distribution of the plasma source power and (or) changing the radial distribution of gas flow in the chamber. Such changes are typically carried out at or above the chamber ceiling, since the plasma source power applicator apparatus is generally at or on top of the ceiling and the process gas injection apparatus is typically a gas distribution plate in the ceiling. One problem is that the distance from the ceiling to the wafer is typically sufficient for diffusion effects to distort a desired distribution of plasma ions and (or) process gas flow between the ideal realized at the ceiling and the actual conditions at the wafer surface. Therefore, the extent to which plasma process uniformity can be improved is significantly limited due to the wafer-to-ceiling gap.

Plasma process control is affected by dissociation of chemical species in the plasma. The degree of dissociation is determined by (among other things) selection of RF plasma source power level, for example. Typically, the degree of dissociation affects all gas chemical species in the chamber, so that generally the same degree of dissociation is experienced by all species in the chamber, although the heavier or more complex molecular species may be somewhat less dissociated than the simpler ones. As a result, it is not generally possible to separately control the dissociation of different chemical species in the reactor chamber. For example, if a high degree of dissociation is desired for one chemical species, all species present in the chamber will experience a significant degree of dissociation. In such a case, for example, it may not be possible to highly dissociate one chemical species in the chamber without at least partially dissociating all species present in the chamber, even the more complex ones. Therefore, the ability to control an etch process is limited by the lack of any independent control over dissociation.

Plasma process control is also affected by the RF electric field at the wafer surface. Typically, the RF electric field at the wafer surface is controlled by the potential of the wafer relative to conductive surfaces of the chamber, such as the side wall or the ceiling. Such control is limited because the side wall is located closest to the wafer edge and furthest from the wafer center, and therefore can create non-uniformities. The ceiling, which presents a uniform conductive plane to the entire wafer, is displaced from the wafer by the wafer-to-ceiling gap which can allow unwanted distortions of what should be a uniform field over the wafer.

### SUMMARY

A plasma reactor is provided for processing a workpiece such as a semiconductor wafer or a dielectric mask. In one aspect, the reactor chamber has a ceiling, a side wall and a workpiece support pedestal inside the chamber and facing the ceiling along an axis of symmetry and defining a chamber volume between the pedestal and the ceiling. An RF plasma source power applicator is provided at the ceiling. An in-situ electrode body inside the chamber lies divides the chamber into upper and lower chamber regions. The in-situ electrode has plural flow-through passages extending parallel to the axis and having different opening sizes. The passages are radially distributed by opening size in accordance with a desired radial distribution of gas flow resistance through the in-situ electrode body. The in-situ electrode further has a conductive electrode element inside the body and permeated by the plural flow-through passages. An electrical terminal is coupled to the conductive electrode element.

In one aspect, the in-situ electrode body has inner and outer concentric gas manifolds, each coupled to its own external gas supply port. Inner and outer concentric zones of gas injection orifices in a bottom surface of the in-situ electrode body are coupled to the inner and outer gas manifolds.

In another aspect, a voltage source, such as a D.C. voltage source, ground or an RF (VHF) voltage source may be coupled to the in-situ electrode body. The body may be formed of an insulating material such as a ceramic material and have a conductive layer within its interior. Alternatively, the entire body itself may be semiconductive material such as a doped ceramic.

### BRIEF DESCRIPTION OF THE DRAWINGS

So that the manner in which the exemplary embodiments of the present invention are attained and can be understood in detail, a more particular description of the invention, briefly summarized above, may be had by reference to the embodiments thereof which are illustrated in the appended drawings. It is to be appreciated that certain well known processes are not discussed herein in order to not obscure the invention.

FIG. 1 is a simplified cut-away view of a plasma reactor having an in-situ electrode.

FIG. 2 depicts a similar reactor in greater detail.

FIGS. 3A, 3B, 3C and 3D are plan views of different embodiments of the in-situ electrode of the reactor of FIG. 1.

FIG. 4 is a plan view of one of the in-situ electrodes of FIGS. 3A, 3B, 3C or 3D.

FIGS. 5 and 6 are perspective and plan views, respectively, of another embodiment of the in-situ electrode of the reactor of FIG. 1.

FIG. 7 depicts an optional feature of the in-situ electrode of FIGS. 5 and 6.

FIG. 8 is a detailed plan view of the in-situ electrode of FIGS. 5 and 6 illustrating the inner and outer internal gas flow manifolds and gas injection orifices.

FIG. 9 is a partial cut-away cross-sectional view corresponding to FIG. 8.

FIGS. 10 and 11 depict one possible implementation of the in-situ electrode of FIGS. 5 and 6.

FIGS. 12A, 12B, 12C, 12D and 12E depict different cross-sections of the in-situ electrode of the reactor of FIG. 1.

To facilitate understanding, identical reference numerals have been used, where possible, to designate identical elements that are common to the figures. It is contemplated that elements and features of one embodiment may be beneficially incorporated in other embodiments without further recitation. It is to be noted, however, that the appended drawings illustrate only exemplary embodiments of this invention and are therefore not to be considered limiting of its scope, for the invention may admit to other equally effective embodiments.

### DETAILED DESCRIPTION

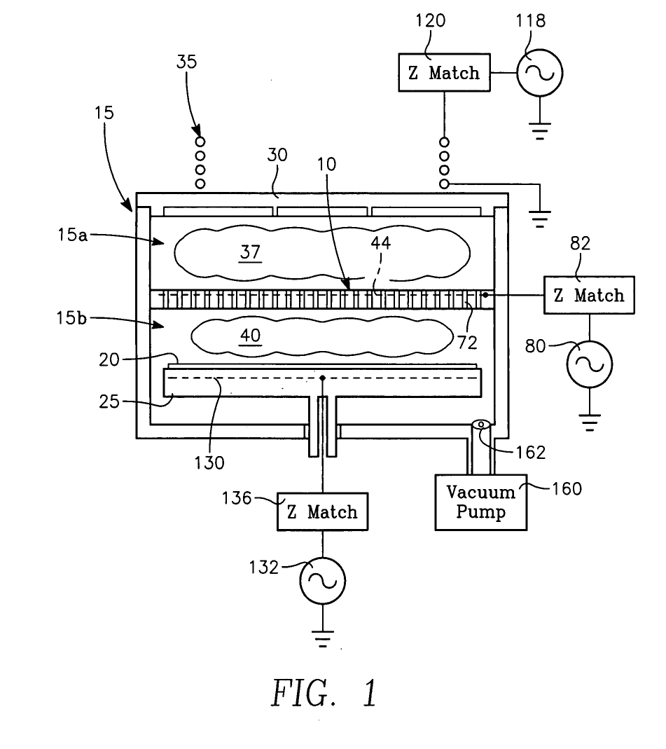

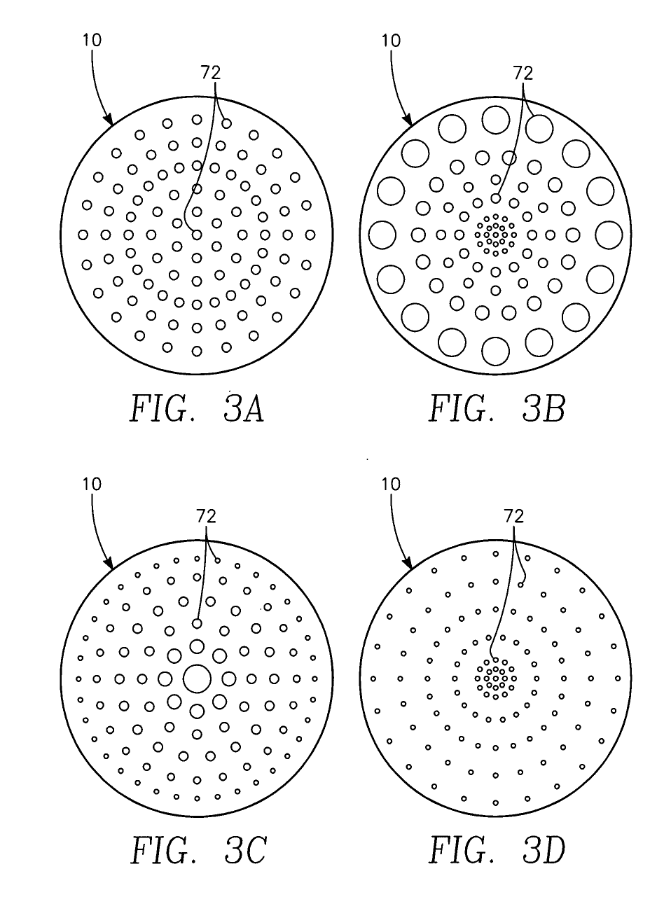

FIG. 1 is a conceptual illustration of an in-situ electrode/gas distribution plate 10 in a plasma reactor chamber 15 for processing a workpiece 20 supported on a workpiece support pedestal 25. An RF plasma source power applicator is provided, which may be either the chamber ceiling 30 (acting as an electrode) or a coil antenna 35 overlying the ceiling 30. Plasma 37 is formed in the upper region 15a of the chamber 15 above the electrode/plate 10. The in-situ electrode/gas distribution plate 10 has passages 72 in accordance with one of the patterns depicted in FIGS. 3A, 3B, 3C or 3D that permit plasma to pass through it from the upper chamber region 15a to the lower region 15b of the chamber 15. This permits a lesser plasma (lower density plasma) 40 to form in the lower region 15b. The in-situ electrode/gas distribution plate 10 may be formed of a dielectric material and have a conductive layer 44 (dashed line in FIG. 1) formed internally. The conductive layer 44 may be connected to an electrical potential, such as an RF power source 80 (through an impedance match 82) or to ground. If it is connected to ground, then the in-situ electrode 10 (specifically, the conductive layer 44) can provide a ground reference for RF bias power applied to the pedestal 25. Alternatively (or in addition), VHF power applied to the conductive layer 44 can promote plasma ion generation in the lower chamber region 15b.

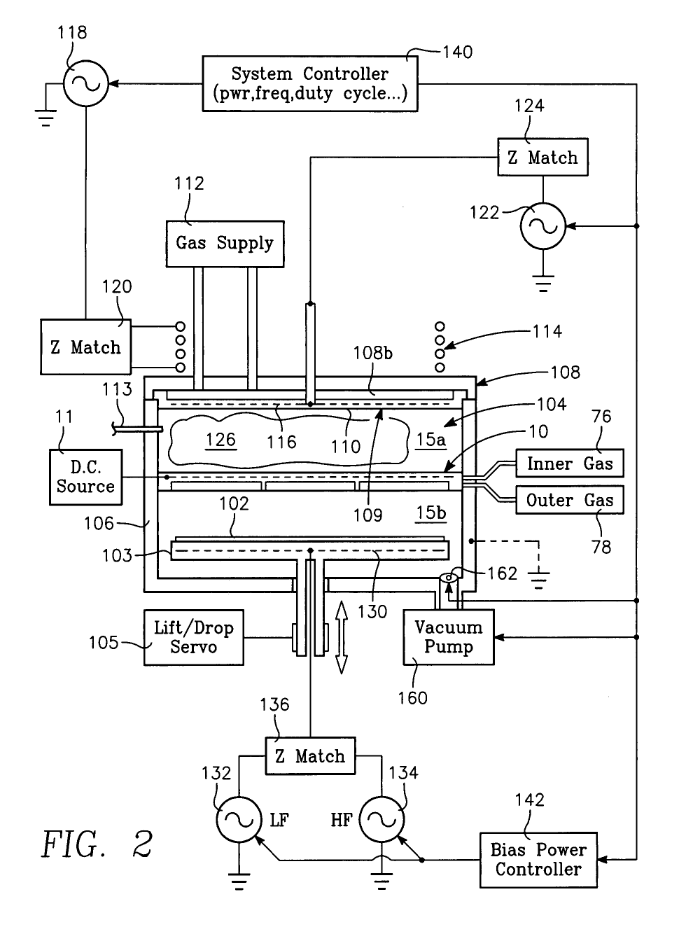

FIG. 2 one example of a type of plasma reactor in which the in-situ electrode 10 of FIG. 1 may be employed. The reactor of FIG. 2 is for processing a workpiece 102, which may be a semiconductor wafer, held on a workpiece support 103, which may (optionally) be raised and lowered by a lift servo 105. The reactor consists of a chamber 104 bounded by a chamber sidewall 106 and a ceiling 108. The ceiling 108 may comprise a gas distribution showerhead 109 having small gas injection orifices 110 in its interior surface, the showerhead 109 receiving process gas from a process gas supply 112. In addition, process gas may be introduced through gas injection nozzles 113. The reactor includes both an inductively coupled RF plasma source power applicator 114 and a capacitively coupled RF plasma source power applicator 116. The inductively coupled RF plasma source power applicator 114 may be an inductive antenna or coil overlying the ceiling 108. In order to permit inductive coupling into the chamber 104, the gas distribution showerhead 109 may be formed of a dielectric material such as a ceramic. The VHF capacitively coupled source power applicator 116 is an electrode which may be located within the ceiling 108 or within the workpiece support 103. In an alternative embodiment, the capacitively coupled source power applicator 116 may consist of an electrode within the ceiling 108 and an electrode within the workpiece support 103, so that RF source power may be capacitively coupled from both the ceiling 108 and the workpiece support 103. (If the electrode is within the ceiling 108, then it may have multiple slots to permit inductive coupling into the chamber 104 from an overhead coil antenna.) An RF power generator 118 provides high frequency (HF) power (e.g., within a range of about 10 MHz through 27 MHz) through an optional impedance match element 120 to the inductively coupled source power applicator 114. Another RF power generator 122 provides very high frequency (VHF) power (e.g., within a range of about 27 MHz through 200 MHz) through an optional impedance match element 124 to the capacitively coupled power applicator 116.

The efficiency of the capacitively coupled power source applicator 116 in generating plasma ions increases as the VHF frequency increases, and the frequency range preferably lies in the VHF region for appreciable capacitive coupling to occur. As indicated symbolically in FIG. 2, power from both RF power applicators 114, 116 is coupled to a bulk plasma 126 within the chamber 104 formed over the workpiece support 103. RF plasma bias power is capacitively coupled to the workpiece 102 from an RF bias power supply coupled to (for example) an electrode 130 inside the workpiece support 103 and underlying the wafer 102. The RF bias power supply may include a low frequency (LF) RF power generator 132 and another RF power generator 134 that may be either a medium frequency (MF) or a high frequency (HF) RF power generator. An impedance match element 136 is coupled between the bias power generators 132, 134 and the workpiece support electrode 130. A vacuum pump 160 evacuates process gas from the chamber 104 through a valve 162 which can be used to regulate the evacuation rate. The evacuation rate through the valve 162 and the incoming gas flow rate through the gas distribution showerhead 109 determine the chamber pressure and the process gas residency time in the chamber.

The plasma ion density increases as the power applied by either the inductively coupled power applicator 114 or VHF capacitively coupled power applicator 116 is increased. However, they behave differently in that the inductively coupled power promotes more dissociation of ions and radicals in the bulk plasma and a center-low radial ion density distribution. In contrast, the VHF capacitively coupled power promotes less dissociation and a center high radial ion distribution, and furthermore provides greater ion density as its VHF frequency is increased.

The inductively and capacitively coupled power applicators may be used in combination or separately, depending upon process requirements. Generally, when used in combination, the inductively coupled RF power applicator 114 and the capacitively coupled VHF power applicator 116 couple power to the plasma simultaneously, while the LF and HF bias power generators simultaneously provide bias power to the wafer support electrode 130. The simultaneous operation of these sources enables independent adjustment of the most important plasma processing parameters, such as plasma ion density, plasma ion radial distribution (uniformity), dissociation or chemical species content of the plasma, sheath ion energy and ion energy distribution (width). For this purpose, a source power controller 140 regulates the source power generators 118, 122 independently of one another (e.g., to control their ratio of powers) in order to control bulk plasma ion density, radial distribution of plasma ion density and dissociation of radicals and ions in the plasma. The controller 140 is capable of independently controlling the output power level of each RF generator 118, 122. In addition, or alternatively, the controller 140 is capable of pulsing the RF output of either one or both of the RF generators 118, 122 and of independently controlling the duty cycle of each, or of controlling the frequency of the VHF generator 122 and, optionally, of the HF generator 118. In addition, a bias power controller 142 controls the output power level of each of the bias power generators 132, 134 independently in order to control both the ion energy level and the width of the ion energy distribution.

The in-situ electrode 10 in the reactor of FIG. 2 is installed in a plane between the workpiece support pedestal 103 and the ceiling 108. In one aspect, the in-situ electrode 10 is formed of an insulating material, such as a ceramic (e.g., aluminum nitride).

Referring to FIGS. 3A-3D, the in-situ electrode passages 72 may be round or circular and may be of a uniform diameter (FIGS. 3A and 3D), or may be in a pattern of increasing diameter with radial location (FIG. 3B), or may be in a pattern of decreasing diameter with radial location (FIG. 3C), or may be of a non-uniform distance between passages 72, for example with greater density at the center and least density at the outer radius (FIG. 3D).

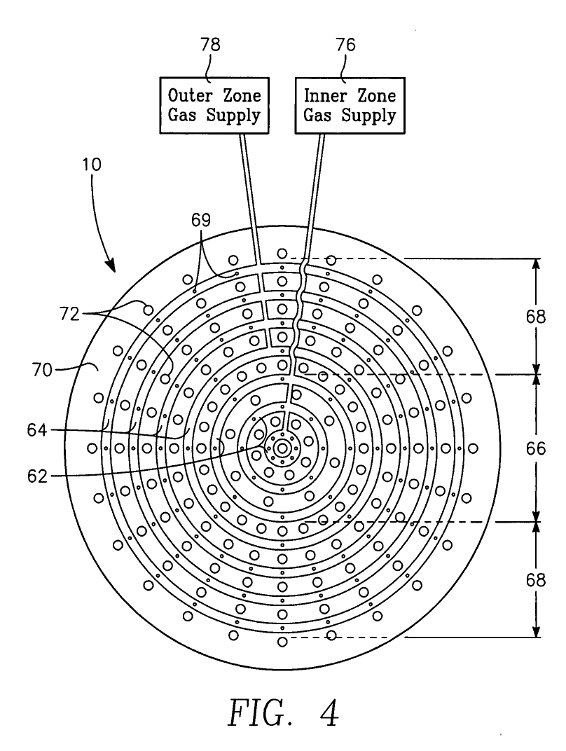

Referring now to FIG. 4, the internal features of the in-situ electrode 10 of FIG. 4 further include inner and outer gas manifolds 62, 64, inner and outer groups 66, 68 of gas injection orifices 69 in the bottom surface 70 of the in-situ electrode 10, and axial passages 72 formed through the in-situ electrode 10 that permit plasma to flow from the upper chamber region 15a through the in-situ electrode 10 to the lower chamber region 15b of FIG. 1. As shown in FIGS. 3B and 3C, the size or area of the passages 72 may vary as a function of radial location on the in-situ electrode 10, in order to introduce a non-uniformity in flow rate distribution through the in-situ electrode 10. This flow rate distribution non-uniformity may be chosen to off-set or precisely compensate for a plasma ion density non-uniformity that is otherwise inherent in the reactor. In the illustrated example, the radial distribution of passage size is such that the smallest passages 72 are nearest the center while the largest ones are nearest the periphery. This compensates for a radial distribution of plasma ion density that is center high. Of course, another distribution of passage size may be chosen, depending upon the desired effect and reactor characteristics.

The reactor of FIG. 2 further includes inner and outer process gas supplies 76, 78 shown in FIG. 4 coupled to respective ones of the inner and outer gas manifolds 62, 64 of the in-situ electrode 10. As shown in FIG. 1, RF power generator 80 is coupled through an impedance match 82 to the conductive layer 44 of the in-situ electrode 10. Alternatively, the conductive layer 44 may be coupled to ground. Or, the conductive layer 44 may be coupled to a D.C. voltage source.

The presence of the in-situ electrode 10 creates different process conditions in the two regions 15a, 15b above and below the in-situ electrode 10 respectively. The upper chamber region 15a has a higher chamber pressure, due to the gas flow resistance through the in-situ electrode passages 72, which favorable for an inductively coupled plasma source. The plasma density and the electron temperature is greater in the upper chamber region 15a, which leads to greater dissociation of chemical species in the upper chamber 15a. The dissociation in the lower chamber is much less because the electron temperature is lower, the plasma ion density is lower and the pressure is lower. Moreover, because of the lower pressure of the bottom chamber region 15b, there are less collisions, so that the ion trajectory is more narrowly distributed about the vertical direction near the wafer surface, a significant advantage.

In accordance with one aspect, the reactor of FIG. 2 may be employed to carry out a unique process in which certain selected chemical species are highly dissociated while others are not. This is accomplished by introducing the chemical species for which a high degree of dissociation is desired through the ceiling gas distribution plate 108b while introducing other chemical species for which little or no dissociation is desired from either or both of the inner and outer gas supplies 76, 78 to the in-situ electrode/gas distribution plate 10. For example, high reactive etch species can be produced by introducing simpler fluoro-carbon gases through the ceiling gas distribution plate 108b, which are dissociated in the high density plasma in the upper region 15a. Very complex carbon-rich species can be produced by introducing complex fluoro-carbon species from the gas supplies 76, 78 to the in-situ electrode 10, which can reach the workpiece surface with little or no dissociation. This greatly increases the range of dissociation of species reaching the workpiece to encompass virtually no dissociation (for species introduced through the in-situ electrode 10) and completely or highly dissociated species (for species introduced through the ceiling gas distribution plate 108b). It also makes the control of dissociation of the two sets of species independent. Such independent control is achieved by producing different process conditions in the upper and lower chamber regions 15a, 15b. The dissociation in the upper region 15a can be controlled by varying the RF source power applied to the coil antenna(s) 114 or to the ceiling electrode 116, for example. In general, dissociation in each of the two regions 15a, 15b is controlled by controlling the RF plasma source power level (e.g., RF generators 118, 124) and the chamber pressure (by controlling the vacuum pump 160) and the gas flow rates to the different regions 15a, 15b.

Because the in-situ electrode/gas distribution plate 10 is closer to the workpiece or wafer 102 than the ceiling gas distribution plate 108b, the radial distribution of active species across the workpiece surface is far more responsive to changes gas flow apportionment between the inner and outer gas manifolds 62, 64, because the diffusion is so minimal. The close proximity of the in-situ electrode 10 to the workpiece 102 also causes the distribution of plasma ions across the workpiece surface to be highly responsive to the distribution of plasma flow through the axial openings 72 of the in-situ electrode 10. Thus, the radial distribution of etch rate across the workpiece surface may be improved (e.g., to a more uniform distribution) by apportioning process gas flow to the inner and outer manifolds 62, 64 of the in-situ electrode and by providing a non-uniform distribution of opening sizes of the axial openings 72 across the in-situ electrode 10.

The volume or height of each of the upper and lower chamber regions 15a, 15b can be adjusted, for example, by raising or lowering either the in-situ electrode 10 or the support pedestal 103 using the actuator 105. By reducing the distance from the wafer 102 to the in-situ electrode 10, the electrode-to-wafer path length is reduced to reduce collisions that would deflect ions from a desired vertical trajectory established by the electric field between the workpiece and the in-situ electrode 10. The volume of the upper chamber region 15a can be adjusted to optimize the operation of the inductively coupled plasma source power applicator 114. In this way, the two chamber regions 15a, 15b can have entirely different process conditions. The upper region 15a can have maximum ion density and maximum volume for maximum dissociation, high pressure and its own set of process gas species (e.g., lighter or simpler fluorocarbons) while the lower region 15b can have minimal ion density, lower pressure, less volume and minimal dissociation.

In accordance with an alternative aspect, the entire in-situ electrode 10 can be rendered conductive by forming it entirely of a semiconductive material or ceramic such as doped aluminum nitride.

The in-situ electrode 10 has different modes of use: One set of process gases may be introduced through the ceiling gas distribution plate 108b into the plasma generation region of the upper chamber 15a, while simultaneously a different set of processes gas may be introduced into the chamber region 15b below the plasma generation region through the in-situ electrode 10 much closer to the workpiece 102.

The gases in the upper and lower regions 15a, 15b may be subject to different process conditions: in the upper region, the ion density and pressure may be higher for greater dissociation of species, while in the lower region, the ion density is less and the pressure is less, for a narrower ion velocity distribution about the true vertical and less dissociation.

The inner and outer gas manifolds or zones 62, 64 of the in-situ electrode 10 may be controlled independently to adjust the radial distribution of process gases introduced through the in-situ electrode 10, the active species distribution at the workpiece surface being much more responsive to such changes because of the closer proximity of the in-situ electrode 10 to the workpiece 102.

The range of dissociated species can be significantly increased by generating highly dissociated species in the upper chamber region 15a and introducing heavier species through the in-situ electrode 10 into the lower region 15b which experience little or no dissociation.

Uniformity of the bias RF electrical field at the workpiece surface can be achieved by employing the conductive layer 44 of the in-situ electrode 10 as a ground reference or as an electrical potential reference, by connecting the conductive layer 44 either to ground or to an RF (HF or LF) potential source 80. The close proximity of the in-situ electrode 10 offers a close uniform plane for establishing a more uniform RF bias field at the workpiece. In one aspect, the RF bias generator 132 or 134 can be coupled across the workpiece support pedestal electrode 130 and the in-situ electrode conductive layer 44.

The gas flow distribution through the axial passages 72 of the in-situ electrode can be rendered non-uniform to compensate for a chamber design that otherwise would produce a center-high or center-low distribution of plasma ion density. This feature may be realized by providing the different passages 72 with differing areas or opening sizes, and distributing those sizes according (e.g., larger opening nearer the center and smaller openings nearer the periphery, or vice versa.

A D.C. voltage source 11 (shown in FIG. 2) may be applied to the in-situ electrode 10.

In this case, the electrode 10 may be formed entirely of a conductive or semi-conductive material (e.g., doped aluminum nitride), and the conductive layer 44 may be eliminated.

The volumes of the upper and lower chamber regions 15a, 15b may be adjusted to optimize conditions in those two regions, for example by raising or lowering the pedestal 103. For example, if an inductively coupled source power applicator 14 is employed to generate the plasma in the upper chamber region 15a, then its performance may be enhanced by increasing the volume of the upper chamber region. This change would also tend to increase the residency time of gases in the plasma in the upper chamber region 15a, thereby increasing dissociation. The volume of lower chamber region 15b may be decreased in order to reduce ion collisions in that region and thereby achieve a narrower distribution of ion velocity profile about the vertical direction. This feature may improve plasma process performance in regions of the workpiece surface having deep high aspect ratio openings.

A low density capacitively coupled plasma source could be established in the lower chamber region 15a by coupling a VHF power generator 80 to the conductive layer 44 (of the in-situ electrode 10). The RF return terminal of the VHF generator can be connected to the support pedestal electrode 130 to establish a VHF electric field in the lower chamber region 15b. In this case, RF filters can be employed to avoid conduction between the HF and VHF power sources 132, 80. For example, if the in-situ electrode 10 (e.g., its conductive layer 44) functions as a ground plane for the HF bias source 132, then the VHF generator 80 could be coupled to the in-situ electrode through a narrow VHF bandpass filter (not shown), for example. Similarly, if the pedestal electrode 130 is to be a ground plane for the VHF generator 80, then the pedestal electrode 130 may be coupled to ground through a narrow VHF bandpass filter (now shown) to avoid diverting power from the HF or LF generators 132, 134, for example.

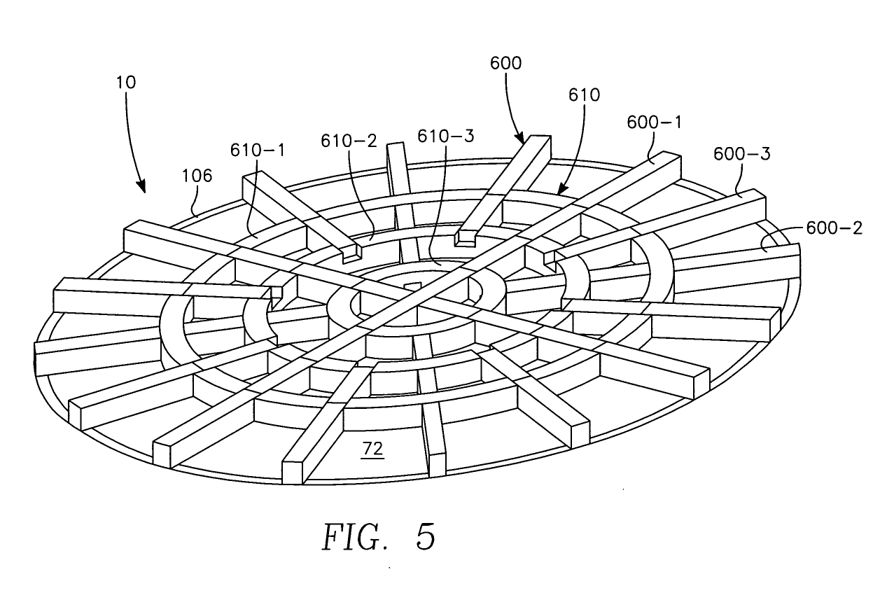

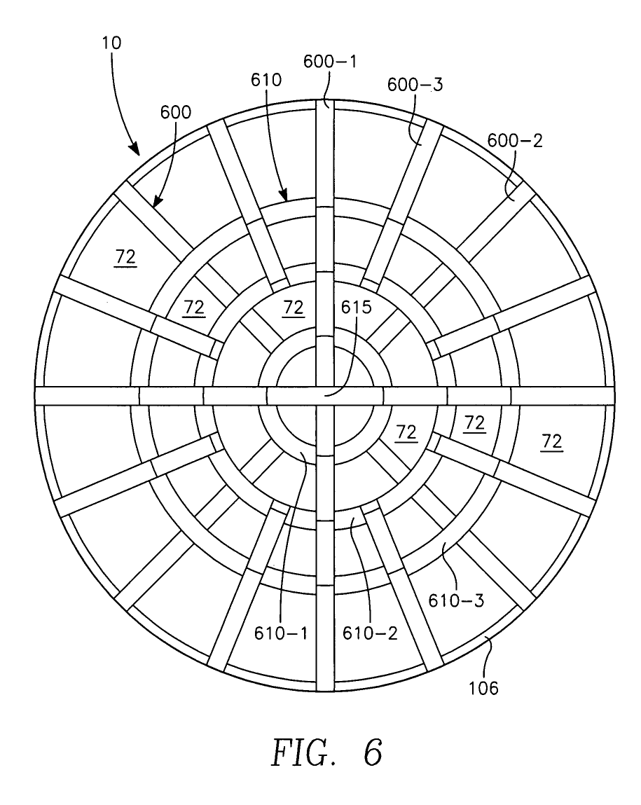

FIGS. 5 and 6 depict an aspect of the invention in which the in-situ electrode body 10 is formed of plural radial spoke members 600 extending between plural concentric circumferential ring members 610. Each flow-through opening 72 is framed between adjacent spoke and ring members 600, 610. In the illustrated structure, the spoke members 600 are of uniform cross-section, and therefore the radial structure inherently causes the openings 72 to progress to ever increasing opening size with radius. This produces the center-high flow resistance feature that can compensate for a center high ion distribution in the upper chamber 15a, in order to provide a more uniform ion distribution in the lower chamber region 15b. As depicted in FIG. 7, the in-situ electrode 10 may be partitioned into center and peripheral sections 10a, 10b, the center section 10b being removable to enhance plasma ion density at the center of the lower chamber region 15b.

In the implementation depicted in FIGS. 5 and 6, there are four concentric ring members 610-1, 610-2, 610-3 and 610-4. There are four primary radial spoke members 600-1 spaced at 90 degree intervals, four secondary radial spoke members 600-2 spaced at 90 degree intervals but rotated by 45 degrees relative to the primary spoke members 600-1, and eight minor spoke members 600-3 spaced from one another at 22.5 degree intervals. The primary spoke members 600-1 extend from the center 615 to the peripheral ring member 610-4. The secondary spoke members 600-2 extend from the innermost ring member 610-1 to the peripheral ring 610-4. The minor spoke members 600-3 extend from the second ring member 610-2 to the peripheral ring 610-4.

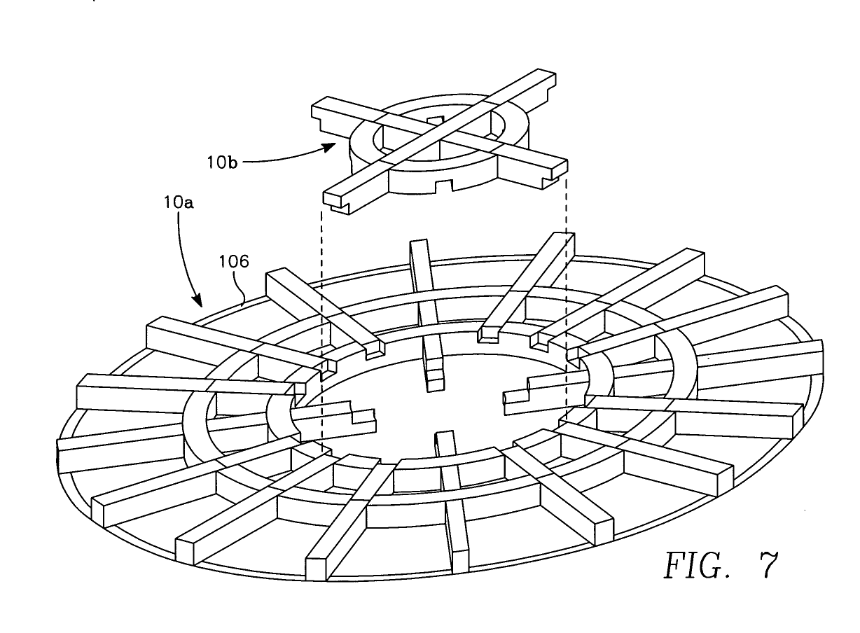

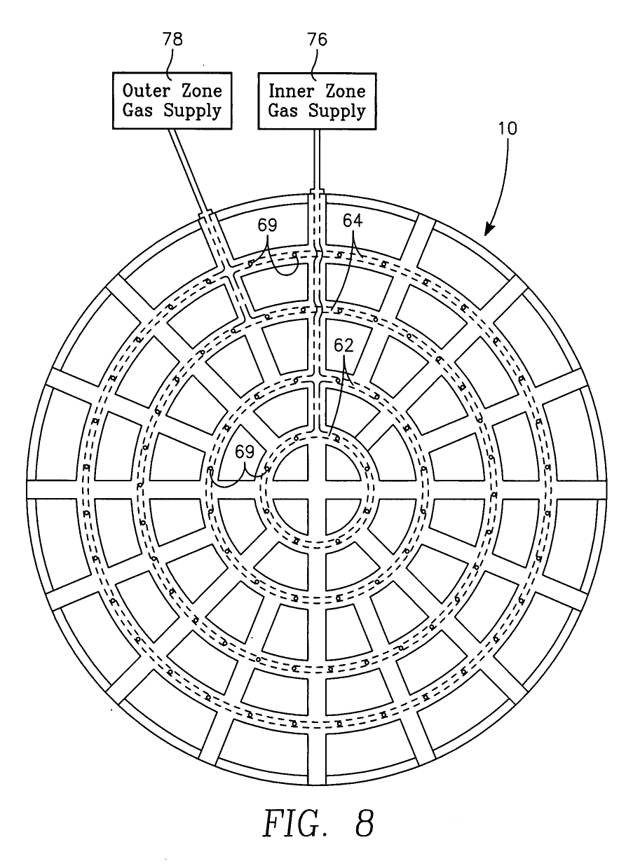

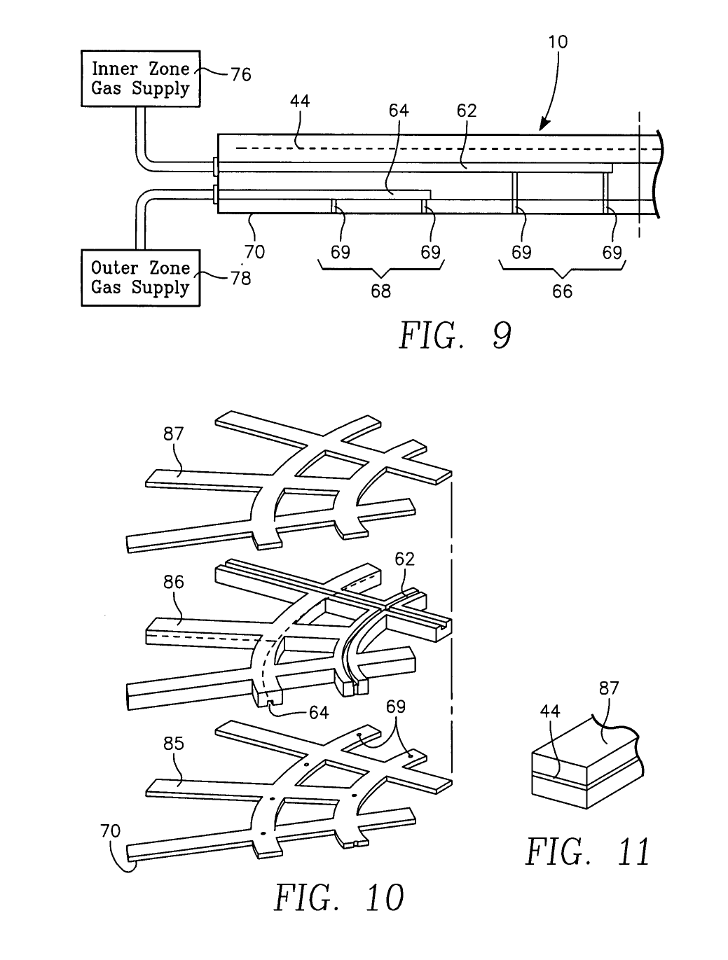

Referring to FIGS. 8 through 10, the in-situ electrode 10 of FIGS. 5 and 6 has an internal conductive (electrode) layer 44 (indicated in dashed line in FIG. 1). It further includes inner and outer gas manifolds 62, 64, inner and outer groups 66, 68 of gas injection orifices 69 in the bottom surface 70 of the in-situ electrode 10. FIG. 10 depicts one possible manner in which the in-situ electrode may be formed of parallel layers 85, 86, 87, of which the bottom layer 85 forms the bottom electrode surface 70 and has the gas injection orifices 69 formed through it. The middle layer 86 includes the gas manifold passages 62, 64. The upper layer 87 caps the middle layer 86 and may include the conductive layer 44, as shown in the enlarged view of FIG. 11. The in-situ electrode 10 of FIG. 8 through FIG. 10 may be formed of a ceramic material such as aluminum nitride. If it desired for the entire body of the in-situ electrode 10 to have some electrical current-carrying ability, then it may be formed of doped aluminum nitride or other doped ceramic, in which case the internal electrode element 44 is unnecessary.

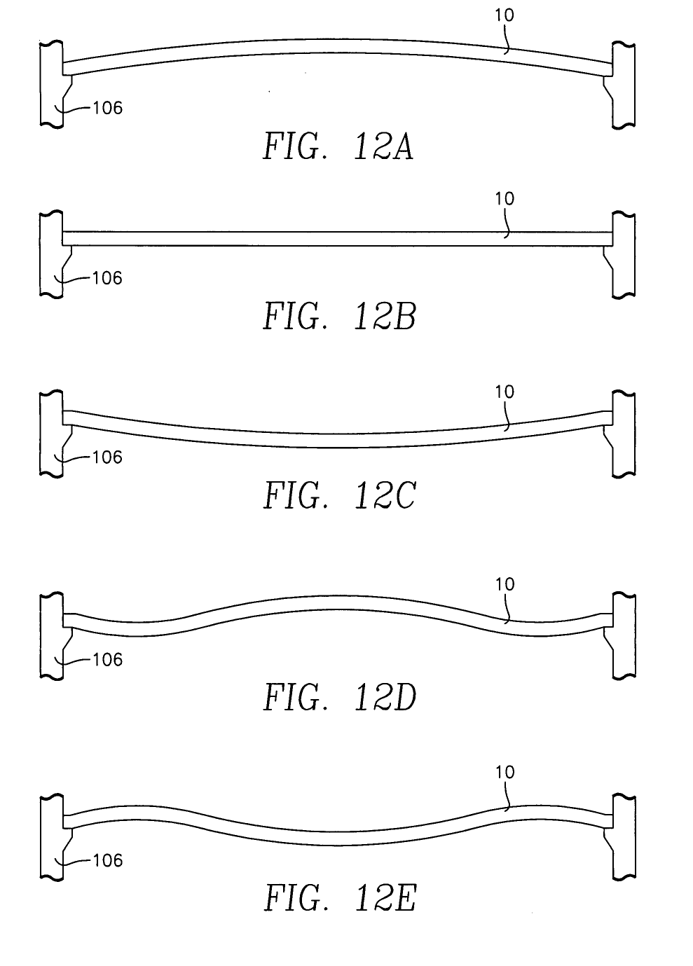

FIGS. 12A, 12B, 12C, 12D and 12E depict embodiments of the in-situ electrode 10 of the reactor of FIG. 1 with different cross-sectional shapes, including a center-high shape (FIG. 12A), a flat shape (FIG. 12B), a center-low shape (FIG. 12C), a center-high and edge-high shape (FIG. 12D), and a center-low and edge-low shape (FIG. 12E). These different shapes may be employed to sculpt the radial distribution of process rate across the workpiece, for example.

While the foregoing is directed to embodiments of the present invention, other and further embodiments of the invention may be devised without departing from the basic scope thereof, and the scope thereof is determined by the claims that follow.

What is claimed is:

1. A plasma reactor comprising:
a reactor chamber having a ceiling, a side wall and a workpiece support pedestal inside said chamber and facing said ceiling along an axis of symmetry and defining a chamber volume between said pedestal and said ceiling;
an RF plasma source power applicator at said ceiling and an RF plasma source power generator coupled to said applicator;
an in-situ electrode body inside said chamber and lying in a plane transverse to said axis and intermediate said ceiling and said support pedestal and dividing said chamber into upper and lower chamber regions, said in-situ electrode comprising:
(a) plural flow-through passages extending parallel to said axis and having different opening sizes, said passages being radially distributed by opening size in accordance with a desired radial distribution of gas flow resistance through said in-situ electrode body;
(b) a conductive electrode element inside said body and permeated by said plural flow-through passages, and an electrical terminal coupled to said conductive electrode element.

2. The reactor of claim 1 wherein said in-situ electrode body further comprises:
a first internal gas manifold;
an external gas supply port coupled to said manifold;
plural gas injection orifices in a bottom surface of said in-situ electrode body facing said support pedestal, said orifices being coupled to said gas manifold.

3. The reactor of claim 2 wherein said first internal manifold comprises a radially inner manifold and said gas injection orifices comprise a radially inner gas injection zone of said in-situ electrode body, and wherein said in-situ electrode body further comprises:
a radially outer internal gas manifold;
a second external gas supply port coupled to said radially outer manifold;
a radially outer gas injection zone comprising a second plurality of gas injection orifices in the bottom surface of said in-situ electrode facing said support pedestal, said second plurality of orifices being coupled to said radially outer gas manifold.

4. The reactor of claim 3 further comprising independent process gas sources coupled to respective ones of said external gas ports of said in-situ electrode body.

5. The reactor of claim 4 further comprising a process gas distribution plate in said ceiling and a further independent process gas source coupled to said gas distribution plate.

6. The reactor of claim 1 further comprising a voltage source coupled to said electrode element, said voltage source comprising one of a ground potential, a D.C. voltage source, an RF voltage source.

7. The reactor of claim 1 wherein said distribution of gas flow resistance is center high whereby to counteract a center-high distribution of plasma ion density in said upper chamber region.

8. The reactor of claim 7 wherein said flow-through passages are located in order of increasing size with radius of location on said in-situ electrode body.

9. The reactor of claim 1 wherein said distribution of gas flow resistance is center low whereby to counteract a center-low distribution of plasma ion density in said upper chamber region.

10. The reactor of claim 9 wherein said flow-through passages are located in order of decreasing size with radius of location on said in-situ electrode body.

11. The reactor of claim 1 further comprising means for adjusting the volumes of said upper and lower chamber regions.

12. The reactor of claim 11 wherein said means for adjusting comprises a lift mechanism coupled to said workpiece support pedestal.

13. The reactor of claim 1 wherein said in-situ electrode body is formed of a ceramic material and said conductive electrode element comprises a planar conductive layer contained within said electrode body.

14. The reactor of claim 1 wherein said in-situ electrode body is formed of a doped ceramic material and constitutes said electrode element.

15. The reactor of claim 1 further comprising a VHF power generator coupled to said conductive electrode element.

16. The reactor of claim 15 wherein said VHF power generator is coupled across said conductive electrode element and said workpiece support pedestal.

17. The reactor of claim 16 further comprising an HF or LF bias power generator coupled to said workpiece support pedestal.

18. The reactor of claim 17 further comprising a VHF bandpass filter coupled between said workpiece support pedestal and ground and an HF or LF bandpass filter coupled between said conductive electrode element of said in-situ electrode body and ground.

19. The reactor of claim 1 wherein said electrode body comprises plural radial members and plural circumferential members, said plural radial and circumferential members framing said flow-through openings of said electrode body.

20. The reactor of claim 19 wherein said electrode body is partitioned into separable inner and outer concentric portions, at least said inner portion being removable to enhance plasma ion density in a center portion of said lower chamber region.

21. A gas distribution plate adaptable for a plasma reactor comprising:
an electrode body configured to be placed inside a plasma chamber in a plane transverse to an axis of said chamber, said electrode body comprising:
(a) plural flow-through passages extending parallel to said axis and having different opening sizes, said passages being radially distributed by opening size in accordance with a desired radial distribution of gas flow resistance through said electrode body in said chamber;
(b) a conductive electrode element inside said electrode body and permeated by said plural flow-through passages, and an electrical terminal coupled to said conductive electrode element.

22. The reactor of claim 21 wherein said electrode body further comprises:
a first internal gas manifold;
an external gas supply port coupled to said manifold;
plural gas injection orifices in a bottom surface of said electrode body, said orifices being coupled to said gas manifold.

23. The reactor of claim 22 wherein said first internal manifold comprises a radially inner manifold and said gas injection orifices comprise a radially inner gas injection zone of said electrode body, and wherein said electrode body further comprises:
a radially outer internal gas manifold;
a second external gas supply port coupled to said radially outer manifold;
a radially outer gas injection zone comprising a second plurality of gas injection orifices in the bottom surface of said electrode, said second plurality of orifices being coupled to said radially outer gas manifold.
